(19) United States
(12) Patent Application Publication
(10) Pub. No.: US 2007/0089665 A1
(43) Pub. Date: Apr. 26, 2007

(54) Instrumental dial

(75) Inventors: Ryo Suzuki, Kariya-city (JP); Yoshinori Araki, Kariya-city (JP); Satoru Tamura, Anjo-city (JP); Kazunaga Kasai, Utsunomiya-shi (JP); Shinji Kamon, Tochigi-ken (JP)

Correspondence Address: Carrier, Blackman & Associates, P.C., 24101 Novi Road #100, Novi, MI, 48375, US

(73) Assignee: Honda Motor Co., Ltd., Tokyo (JP)

(21) Appl. No.: 11/585,478

(22) Filed: Oct. 24, 2006

(30) Foreign Application Priority Data
Oct. 26, 2005 (JP) 2005-311674

(51) Int. Cl. H03J 1/00

(52) U.S. Cl. 116/245

(57) ABSTRACT

An instrumental dial has a plurality of grooves defined in a front surface thereof. Each groove has a pair of side surfaces each comprising a pair of flat surfaces. The flat surface is closer to a rear surface of the instrumental dial than the flat surface. The flat surfaces are inclined by different angles θ1, θ2, respectively, to the direction in which the dial is visually recognized. The angles θ1, θ2 satisfy the relationship of θ1>θ2. The number of times that incoming light is reflected in the groove is increased to greatly reduce the amount of light that leaves the groove and also to disperse outgoing light in various directions. The instrumental dial thus has a novel look provided by a spinning pattern, and has a reduced reflectance for good visibility.

### BACKGROUND OF THE INVENTION

1. Field of the Invention

The present invention relates to an instrumental dial for use in a combination meter or the like mounted on an automobile, for example, for displaying various items of information.

2. Description of the Related Art

One conventional instrumental dial is a dial for use in a pointer instrument, the dial being made of metal and having a surface marked with radial lines. For details, reference should be made to Japanese Laid-Open Patent Publication No. 2003-4495.

Radial lines are applied to display designs of instruments such as a scale and numerals.

When the surface of the conventional instrumental dial is irradiated with external light or illuminating source light, the surface of the conventional instrumental dial reflects the applied light, which enables the viewer of the dial to feel the texture of metal and gives a high-quality looking to the dial.

The radial lines on the surface of the conventional instrumental dial are produced by closely spaced radial grooves each having an extremely small width and depth. Therefore, the instrumental dial has such a high reflectance that the reflected light which is produced when the instrumental dial is irradiated with external light or illuminating source light is intensive enough to dazzle the viewer, resulting in a reduction of the visibility of the dial.

### SUMMARY OF THE INVENTION

It is a general object of the present invention to provide an instrumental dial having a metal-like pattern for a novel look.

A major object of the present invention is to provide an instrumental dial with a reduced reflectance for good visibility.

According to the present invention, there is provided an instrumental dial having a metal-like pattern on a front surface thereof to be visually recognized, the metal pattern comprising a plurality of grooves defined in the front surface, each of the grooves having side surfaces each comprising a plurality of flat surfaces extending obliquely to each other and having different angles with respect to a direction in which the instrumental dial is visually recognized.

A conventional instrumental dial has a metal-like pattern comprising grooves defined in its front surface. Each of the grooves is of a substantially V-shaped cross section and has a pair of side surfaces inclined to the direction in which the instrumental dial is visually recognized and facing each other. Light applied to each of the grooves is applied to either one of the two side surfaces, reflected twice by the side surface, applied to the other side surface, reflected thereby, and travels back in a direction substantially opposite to the direction of the incoming light. As most of the incoming light is reflected back in the direction opposite to the direction of the incoming light, the amount of light which is reduced in the groove is relatively small, or stated otherwise, the metal-like pattern has a high optical reflectance. Depending on how light is applied to the instrumental dial, the metal-like pattern tends to dazzle the viewer of the dial and lower the visibility of the conventional instrumental dial.

With the instrumental dial according to the present invention, each of the side surfaces of each of the grooves does not comprise a single planar surface, but comprises a plurality of flat surfaces extending obliquely to each other and having different angles with respect to a direction in which the instrumental dial is visually recognized. Specifically, each of the grooves of the metal-like pattern is defined by at least four flat surfaces.

Light applied to some of the grooves is reflected by two flat surfaces, i.e., reflected twice, and travels back in a direction which is substantially opposite to the direction in which the incoming light is applied to the grooves. Light applied to other grooves is reflected three or more times and then leaves the grooves. When light is reflected by a flat surface, the reflectance is less than 100%, and the amount of light reflected by the flat surface is smaller than the amount of light applied to the flat surface. Therefore, as the number of times that light is reflected by flat surfaces is greater, then the amount of light reflected by the flat surfaces becomes smaller.

With the instrumental dial according to the present invention, since the number of times that light applied to each of the grooves is reflected until the light goes out of the groove is greater than with the conventional instrumental dial, the reflectance of the metal-like pattern of the instrumental dial according to the present invention is smaller than the reflectance of the metal-like pattern of the conventional instrumental dial. Therefore, the metal-like pattern of the instrumental dial according to the present invention is less liable to dazzle the viewer. The instrumental dial according to the present invention thus has a novel look provided by the metal-like pattern, and has a reduced reflectance for good visibility.

In the instrumental dial according to the present invention, the angles at which the flat surfaces extend with respect to the direction in which the instrumental dial is visually recognized are progressively smaller in a direction away from a rear surface of the instrumental dial.

In the instrumental dial according to the present invention, the flat surfaces include a first flat surface closer to the rear surface of the instrumental dial, and a second flat surface remote from the rear surface, the first flat surface and the second surface being inclined with respect to the direction in which the instrumental dial is visually recognized at an angle θ1 and an angle θ2, respectively, the angles θ1, θ2 satisfying the relationship of θ1>θ2.

The angle between a flat surface and the direction in which the dial is visually recognized is the maximum, i.e., 90 degrees, when the flat surface lies perpendicularly to the direction in which the dial is visually recognized. As the flat surface is inclined to the direction in which the dial is visually recognized, the angle becomes smaller. The angle is minimum, i.e., 0 degree when the flat surface lies parallel to the direction in which the dial is visually recognized. Consequently, as the angle between the flat surface and the direction in which the dial is visually recognized is greater, a greater amount of light which is reflected by the flat surface travels directly back to the viewer, resulting in a greater tendency to dazzle the viewer.

If light is applied to the instrumental dial according to the present invention obliquely to the direction in which the dial is visually recognized, then the light is applied to the flat surfaces of one of the side surfaces of each of the grooves, but is not applied to the flat surfaces of the other side surface of each of the grooves.

Therefore, the instrumental dial according to the present invention is thus more effective to reduce the reflectance of the metal-like pattern.

According to the present invention, there is also provided an instrumental dial having a metal-like pattern on a front surface thereof to be visually recognized, the metal pattern comprising a plurality of grooves defined in the front surface, each of the grooves having a surface which is concave in a direction in which the instrumental dial is visually recognized.

This structure is essentially equivalent to the instrumental dial described above wherein the flat surfaces are smoothly joined to each other, i.e., each of the side surfaces comprises an infinite number of flat surfaces.

The instrumental dial thus constructed also has a novel look provided by the metal-like pattern, and has a reduced reflectance for good visibility.

In the instrumental dial according to the present invention, the grooves extend substantially straight on the front surface.

In the instrumental dial according to the present invention, the grooves extend substantially concentrically to each other on the front surface.

In the instrumental dial according to the present invention, the grooves extend radially on the front surface.

The grooves that extend substantially straight, substantially concentrically to each other, or radially give a better look to the metal-like pattern.

The above and other objects, features, and advantages of the present invention will become more apparent from the following description when taken in conjunction with the accompanying drawings in which preferred embodiments of the present invention are shown by way of illustrative example.

### BRIEF DESCRIPTION OF THE DRAWINGS

FIG. 1 is a fragmentary front elevational view of a combination meter incorporating a dial according to an embodiment of the present invention;

FIG. 2 is a cross-sectional view taken along line II-II of FIG. 1;

FIG. 3 is an enlarged fragmentary cross-sectional view of the dial shown in FIG. 2;

FIG. 4 is a block diagram of an electric circuit arrangement of the combination meter which incorporates the dial according to the embodiment of the present invention;

FIG. 5 is a fragmentary front elevational view of a combination meter incorporating a dial according to another embodiment of the present invention;

FIG. 6 is a fragmentary front elevational view of a combination meter incorporating a dial according to a further embodiment of the present invention; and

FIG. 7 is an enlarged fragmentary cross-sectional view of a conventional instrumental dial.

### DESCRIPTION OF THE PREFERRED EMBODIMENTS

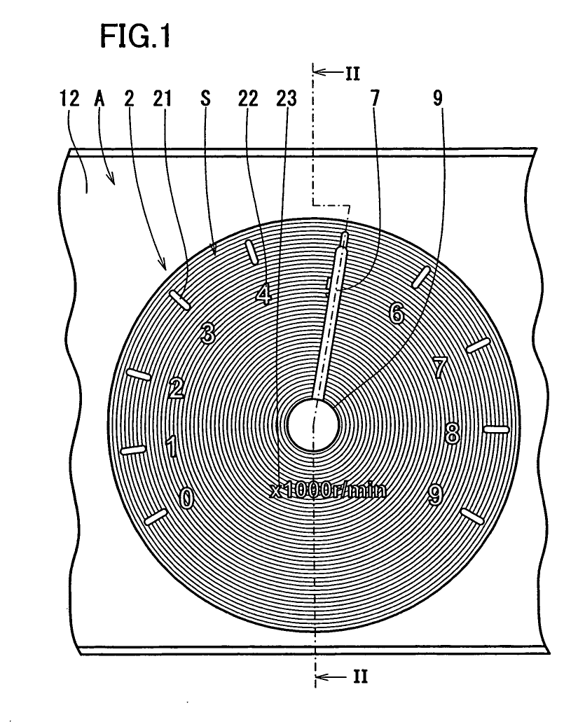

The present invention as applied to a dial 2 (see FIG. 1) mounted in an engine tachometer A as an instrument in a combination meter 1 mounted in the passenger compartment of an automobile will be described in detail with reference to the accompanying drawings.

In FIG. 1, the upward direction is the same as the upward direction of the automobile, and the horizontal direction is the same as the transverse direction of the automobile.

The combination meter 1 is disposed in front of the driver's seat in the passenger compartment of the automobile so as to be visually recognized by the driver on the driver's seat. The combination meter 1 serves to display information, which represents the running speed, the engine rotational speed, etc., relative to the operating state of the automobile, and various other information.

As shown in FIG. 1, the engine tachometer A comprises a dial 2 having a scale, numerals, etc. marked thereon and a pointer 7 angularly movable along the front surface of the dial 2. When the pointer 7 is angularly moved over the front surface of the dial 2 through an angle, the pointer 7 is pointed at a numerical value on the scale which corresponds to the angle, and the driver of the automobile visually recognizes an engine rotational speed that is represented by the numerical value.

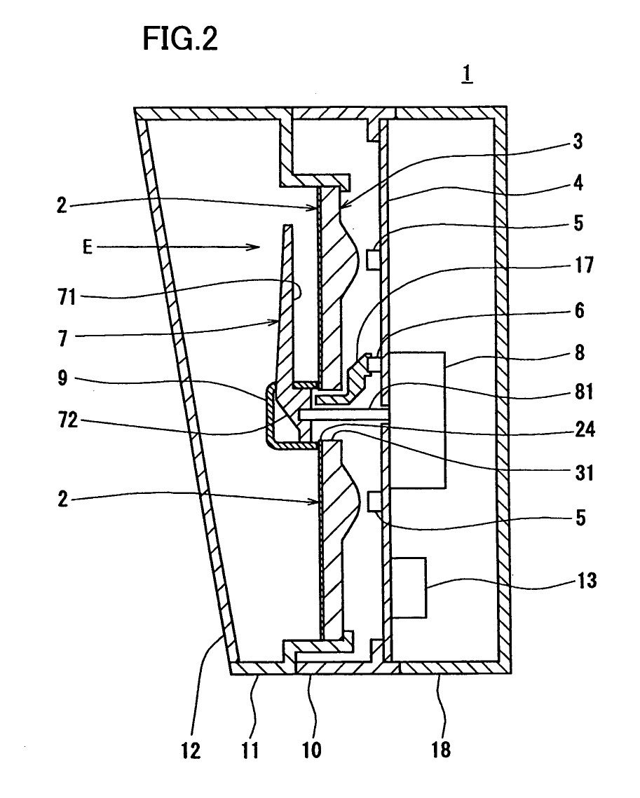

The dial 2 as an instrumental dial comprises a thin plate of metal such as aluminum, stainless steel, or the like. The dial 2 has a scale 21, numerals 22, and characters 23 marked thereon, the scale 21 and the numerals 22 being representative of engine rotational speeds of the automobile in combination with the pointer 7. The scale 21, the numerals 22, and the characters 23 are actually formed as through holes punched through the thin plate of metal by a press. The holes are shaped as the scale 21, the numerals 22, and the characters 23. As shown in FIG. 2, a shaft hole 24 is defined centrally in the dial 2, and a shaft 81 with the pointer 7 mounted one end thereof extends through the shaft hole 24.

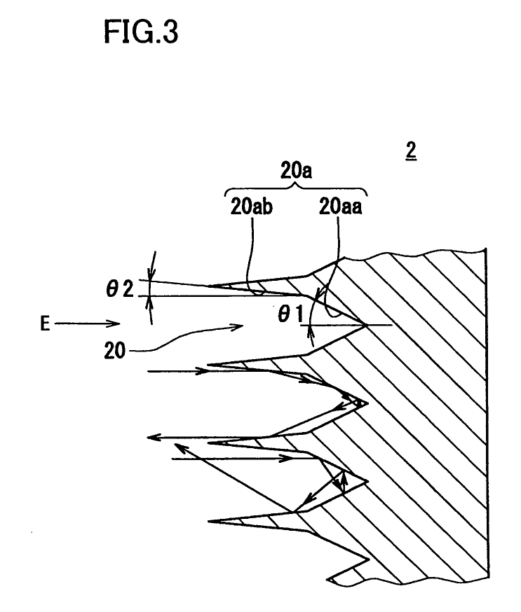

As shown in FIG. 1, a spinning pattern S is provided as a metal-like pattern on the entire front surface of the dial 2. The spinning pattern S comprises a number of concentric circular grooves 20 (see FIG. 3) defined in the front surface of the dial 2. The circular grooves 20 of the spinning pattern S are disposed concentrically to the shaft hole 24 in closely spaced relationship to each other.

As shown in FIG. 3, each of the grooves 20 has a pair of side surfaces 20a as inner wall surfaces which confront each other. Each of the side surfaces 20a comprises a pair of joined flat surfaces 20aa, 20ab extending obliquely to each other. The flat surface 20aa is closer to the rear surface (on the right in FIG. 3) of the dial 2 than the flat surface 20ab, and the flat surface 20ab is remote from the rear surface (on the left in FIG. 3) of the dial 2 than the flat surface 20aa. The flat surfaces 20aa, 20ab are inclined by different angles, respectively, to the direction indicated by the arrow E (see FIGS. 2 and 3) along which the dial 2 is visually recognized, i.e., the direction which is perpendicular to the plane of the dial 2. Specifically, the flat surface 20aa that is closer to the rear surface of the dial 2 is inclined to the direction indicated by the arrow E at an angle θ1, and the flat surface 20ab that is closer to the front surface of the dial 2 is inclined to the direction indicated by the arrow E at an angle θ2. The angles θ1, θ2 satisfy the relationship of θ1>2. Stated otherwise, the angles θ1, θ2 become progressively smaller in a direction from the rear surface of the dial 2.

As shown in FIG. 2, a light guide plate 3 is held in intimate contact with the rear surface of the dial 2. The light guide plate 3 serves to guide light emitted from a light-emitting diode 5 as a light source to the dial 2 for passing through and illuminating the scale 21, the numerals 22, and the characters 23 of the dial 2. The light guide plate 3 is made of a light-permeable material of colorless, transparent acrylic resin or polycarbonate resin. The light guide plate 3 has a through hole 31 defined therein in alignment with the shaft hole 24 in the dial 2. The shaft 81 which extends from a movement 8 positioned behind the light guide plate 3 extends through the through hole 31.

A printed-circuit board 4 supporting an electric circuit of the combination meter 1 is disposed behind the light guide plate 3, i.e., rightward of the light guide plate 3 in FIG. 2.

The printed-circuit board 4 comprises a glass epoxy board or the like. The light-emitting diode 5 is mounted on the printed-circuit board 4. Another light-emitting diode 6 as a light source for emitting light for illuminating the pointer 7 is also mounted on the printed-circuit board 4. A light guide body 17 is mounted on a light-emitting surface of the light-emitting diode 6 for efficiently guiding the light emitted from the light-emitting diode 6 to the pointer 7. The light guide body 17 is made of a light-permeable material of colorless, transparent acrylic resin or polycarbonate resin. In the present embodiment, each of the light-emitting diodes 5, 6 comprises a white light-emitting diode. The movement 8 for turning the pointer 7 is mounted on the printed-circuit board 4.

The movement 8 comprises a crossed coil actuator or a stepping motor, for example. When a voltage is applied to the movement 8 from an external source, the movement 8 generates a torque to turn the shaft 81 about its own axis. The shaft 81 has its tip end extending through the shaft hole 24 in the dial 2 to the front surface of the dial 2. The pointer 7 has its proximal end fixed to the tip end of the shaft 81.

The pointer 7 is made of a light-permeable material of colorless, transparent acrylic resin or polycarbonate resin. When the shaft 81 is turned about its own axis by the movement 8, the pointer 7 is turned in unison with the shaft 81. The pointer 7 has a rear surface 71 colored (e.g., in red) with a colored layer formed by printing or hot stamping. The pointer 7 also has a slanted reflecting surface 72 on its proximal end in facing relation to the tip end of the shaft 81. Light emitted from the light-emitting diode 6 and guided by the light guide body 17 into the pointer 7 is reflected by the reflecting surface 72 toward the tip end of the pointer 7. The reflected light is reflected again by the rear surface 71 toward the driver (also referred to as “viewer”) who is looking at the dial 2. Therefore, the pointer 7 is displayed as emitting light in red.

Since the light-emitting diode 6 in the combination meter 1 which has the dial 2 comprises a white light-emitting diode, the pointer 7 is displayed as emitting light in the color of the colored layer applied to the rear surface 71 of the pointer 7. The color of the colored layer is not necessarily red, but may be orange, green, or any of other colors. Alternatively, a white colored layer or a silver colored layer may be applied to the rear surface 71 of the pointer 7, and the light-emitting diode 6 may be a light-emitting diode for emitting light in a color other than white. In this case, the pointer 7 is displayed as emitting light in the color of light emitted by the light-emitting diode 6.

As shown in FIG. 2, a light-shielding cap 9 is mounted on the pointer 7 in covering relation to the reflecting surface 72 and nearby surfaces of the pointer 7. The light-shielding cap 9 is made of a light-shielding material such as a metal or a black resin material for preventing light emitted by the light-emitting diode 6 from directly entering the eyes of the viewer and dazzling the viewer.

A controller 13 for selectively energizing and de-energizing the light-emitting diodes 5, 6 and controlling the movement 8 for turning the pointer 7 is mounted on the printed-circuit board 4. The controller 13 comprises a microcomputer, for example.

The dial 2, the light guide plate 3, the printed-circuit board 4, and other components referred to above are fixedly housed in a casing 10 which is made of a resin material, for example. The dial 2 has an outer circumferential edge held by a facing frame 11 secured to the casing 10. The facing frame 11 is made of a resin material, for example. A transparent cover 12 is mounted on the front end of the facing frame 11 which is closer to the viewer. As shown in FIG. 2, the transparent cover 12 is in the form of a thin plate of transparent resin or glass. A rear cover 18 is fixed to the rear end of the casing 10. The facing frame 11 serves to provide a clear contour around the dial 2 and hence around the engine tachometer A, giving a neat look to the combination meter 1. The transparent cover 12 and the rear cover 18 serve to keep the combination meter 1 hermetically sealed to prevent dust and water from entering the combination meter 1.

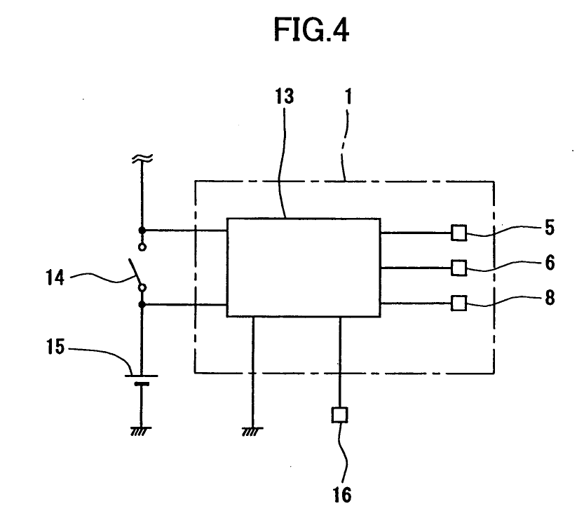

An electric circuit arrangement of the combination meter 1 with the dial 2 will be described below with reference to FIG. 4.

As shown in FIG. 4, the controller 13 is supplied with electric power from a battery 15 at all times. An ignition key switch 14 of the automobile is electrically connected to the controller 13 so that the controller 13 can detect whether the ignition key switch 14 is turned on or off.

The light-emitting diode 5, the light-emitting diode 6, and the movement 8 are electrically connected to the controller 13, as shown in FIG. 4.

A rotation sensor 16 for detecting the engine rotational speed of the automobile is also electrically connected to the controller 13. The rotation sensor 16 applies a detected signal to the controller 13. The rotation sensor 16 detects the rotational speed of the crankshaft of the engine or a shaft which rotates in synchronism with the crankshaft. The rotation sensor 16 comprises an electromagnetic induction coil or a magnetic detector.

When the ignition key switch 14 is turned on by the viewer, the controller 13 detects the turned-on state of the ignition key switch 14, and starts to operate the engine tachometer A, i.e., to energize the light-emitting diodes 5, 6. At the same time, the controller 13 calculates the rotational speed of the engine based on the detected signal from the rotation sensor 16, and actuates the movement 8 to turn the pointer 7 to indicate the calculated engine rotational speed on the dial 2. On the dial 2, the scale 21, the numerals 22, the characters 23, and the pointer 7 are displayed as emitting light, and the pointer 7 is turned by the movement 8 to indicate the rotational speed of the engine.

When the ignition key switch 14 is turned off by the viewer, the controller 13 detects the turned-off state of the ignition key switch 14, and stops operating the engine tachometer A, i.e., to de-energize the light-emitting diodes 5, 6. At the same time, the controller 13 actuates the movement 8 to cause the pointer 7 to indicate the engine rotational speed “0” r/min (revolution per minute) on the dial 2. Alternatively, the controller 13 inactivates the movement 8. If the controller 13 inactivates the movement 8, the shaft 81 coupled to the movement 8 is turned under the bias of a return spring (not shown) until the pointer 7 indicates the engine rotational speed “0” r/min.

Advantages provided by the spinning pattern S on the dial 2, particularly those affecting the visibility of the dial 2, will be described below.

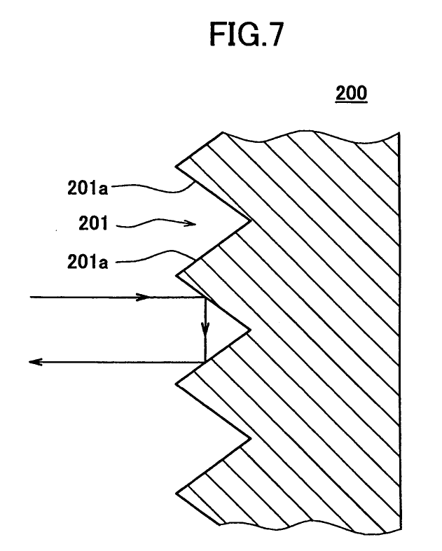

As shown in FIG. 7, a conventional instrumental dial 200 has grooves 201 defined in its front surface. Each of the grooves 201 is of a substantially V-shaped cross section and has a pair of side surfaces 200a as inner wall surfaces. Each of the side surfaces 200a comprises a single planar surface. Light applied to the groove 201 travels and goes out of the groove 201 as indicated by the arrows in FIG. 7. Specifically, the incoming light is reflected by one of the side surfaces 200a and then by the other side surface 200a to travel back substantially in a direction opposite to the direction in which the light comes in. Stated otherwise, the light applied to the groove 201 is reflected twice by the side surfaces 200a and then goes out of the groove 201. As most of the incoming light is reflected back in the direction opposite to the direction of the incoming light, the amount of light which is reduced in the groove 201 is relatively small, and the amount of reflected light is relatively large. Consequently, the viewer is dazzled by the light reflected by the conventional instrumental dial 200, and the visibility of the conventional instrumental dial 200 is relatively low.

According to the present embodiment, as shown in FIG. 3, each of the side surfaces 20a of each of the grooves 20 defined in the dial 2 comprises a pair of joined flat surfaces 20aa, 20ab extending obliquely to each other. The flat surface 20aa is closer to the rear surface of the dial 2 than the flat surface 20ab, and the flat surface 20ab is remote from the rear surface of the dial 2 than the flat surface 20aa. The flat surfaces 20aa, 20ab are inclined by different angles θ1, θ2, respectively, to the direction indicated by the arrow E (see FIGS. 2 and 3) along which the dial 2 is visually recognized, and the angles θ1, θ2 satisfy the relationship of θ1>θ2.

Light applied to each of the grooves 20 travels and goes out of the groove 20 as indicated by the arrows in FIG. 3. Specifically, the light applied to the groove 20 is reflected four or five times by the side surfaces 20a and then goes out of the groove 20. Since the incoming light is reflected much more often in the groove 20 than in the groove 201 of the conventional instrumental dial 2, the amount of light which is reduced in the groove 20 is relatively large. In other words, the amount of light reflected back from the groove 20 is much smaller than the amount of light reflected back from the groove 201 of the conventional instrumental dial 2.

As shown in FIG. 3, when the light applied to the groove 20 is reflected back and goes out of the groove 20, it is dispersed in various directions.

Because the amount of light reflected back from the groove 20 is greatly reduced and the reflected light is dispersed in many directions, the amount of light reflected from the spinning pattern S to the eyes of the viewer is also greatly reduced. Though the amount of light reflected from the spinning pattern S is reduced, the viewer is still capable of visually recognizing the spinning pattern S. Therefore, the spinning pattern S is effective enough to give a novel look to the dial 2.

The dial 2 thus has a novel look provided by the spinning pattern S as a metal-like pattern, and has a reduced reflectance for good visibility.

The amount of light reflected from the groove 20 is greater as the area of the groove 20 for receiving light is greater. If light is applied to the groove 20 obliquely to the direction in which the dial 2 is visually recognized, then as the angle between the direction in which the light is applied to the groove 20 and the direction in which the dial 2 is visually recognized increases from 0, the light is no longer applied to one of the flat surfaces 20aa, 20ab when the angle is equal to or greater than a certain angle. Stated otherwise, when the angle between the above directions is equal to or greater than a certain angle, the amount of light reflected from the groove 20 is reduced to one-half.

According to the present embodiment, the angular range in which the incoming light is applied to both the flat surfaces 20aa, 20ab of the groove 20 is smaller than with the conventional instrumental dial. In other words, the angular range of the incoming light in which the amount of light reflected from the groove 20 is greater than with the conventional instrumental dial.

Consequently, the dial 2 has a novel look provided by the spinning pattern S as a metal-like pattern, and has a reduced reflectance for good visibility.

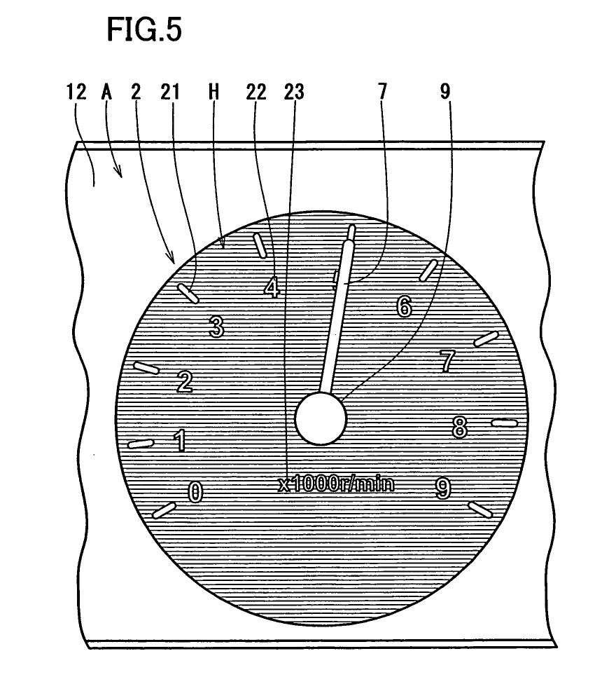

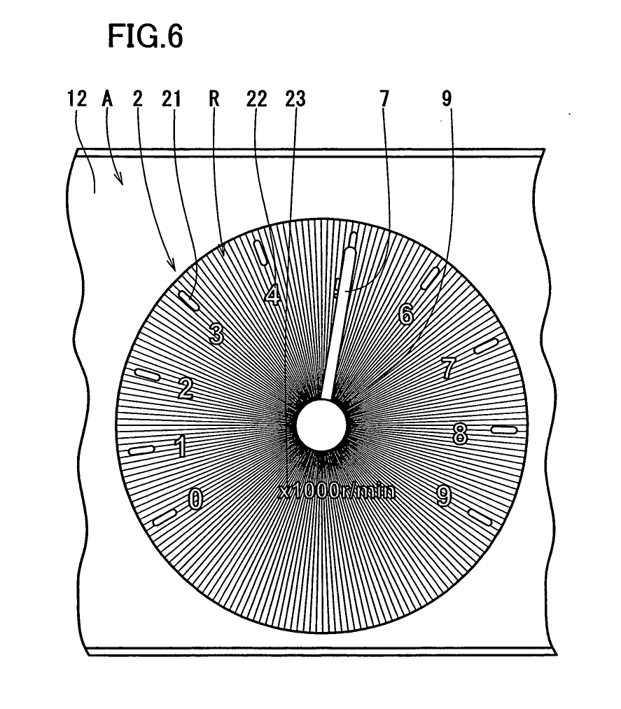

According to the present embodiment, the metal-like pattern is in the form of the spinning pattern S which comprises a number of concentric circular grooves 20. However, the metal-like pattern is not limited to the spinning pattern S, but may be a hairline pattern H (see FIG. 5) comprising a number of substantially straight lines or wavy lines or a radial pattern R (see FIG. 6) comprising a number of radial straight lines.

In the present embodiment, the dial 2 comprises a thin plate of metal. However, the dial 2 may be made of any of other materials, e.g., a resin material, or of a combination of different materials, e.g., a thin plate of metal and a resin plate superposed on the reverse side of the thin plate of metal.

In the engine tachometer A with the dial 2, the light-emitting diode 5 is used as a light source for illuminating the dial 2 and the light-emitting diode 6 is used as a light source for illuminating the pointer 7. However, at least one of the light-emitting diodes 5, 6 may be replaced with any of other types of light sources, e.g., an electric bulb, a discharge lamp, an EL panel, or the like.

In the present embodiment, the dial 2 is incorporated in the engine tachometer A in the combination meter 1 that is disposed in the passenger compartment of the automobile. However, the dial 2 may be incorporated in any of various other meters, e.g., a speedometer for indicating the running speed of an automobile, a fuel meter for indicating the remaining amount of fuel in a fuel tank, or a water temperature meter for indicating the temperature of an engine coolant. The combination meter 1 may have a plurality of instruments each having the dial 2 according to the present invention.

The dial 2 according to the present invention may be incorporated in an instrument for use on apparatus other than automobiles, i.e., an instrument on any of various other apparatus for consumer use.

Although certain preferred embodiments of the present invention have been shown and described in detail, it should be understood that various changes and modifications may be made therein without departing from the scope of the appended claims.

What is claimed is:

1. An instrumental dial having a metal-like pattern on a front surface thereof to be visually recognized, said metal-like pattern comprising a plurality of grooves defined in said front surface, each of said grooves having side surfaces each comprising a plurality of flat surfaces extending obliquely to each other and having different angles with respect to a direction in which the instrumental dial is visually recognized.

2. An instrumental dial according to claim 1, wherein the angles at which said flat surfaces extend with respect to said direction in which the instrumental dial is visually recognized are progressively smaller in a direction away from a rear surface of said instrumental dial.

3. An instrumental dial according to claim 1, wherein said flat surfaces include a first flat surface closer to a rear surface of the instrumental dial which is remote from said front surface, and a second flat surface remote from said rear surface, said first flat surface being inclined to said direction in which the instrumental dial is visually recognized at an angle θ1, said second flat surface being inclined to said direction at an angle θ2, said angles θ1, θ2 satisfying the relationship of θ1>θ2.

4. An instrumental dial according to claim 1, wherein said grooves extend substantially straight on said front surface.

5. An instrumental dial according to claim 1, wherein said grooves extend substantially concentrically to each other on said front surface.

6. An instrumental dial according to claim 1, wherein said grooves extend radially on said front surface.

7. An instrumental dial having a metal-like pattern on a front surface thereof to be visually recognized, said metal-like pattern comprising a plurality of grooves defined in said front surface, each of said grooves having a surface which is concave in a direction in which the instrumental dial is visually recognized.

8. An instrumental dial according to claim 7, wherein said grooves extend substantially straight on said front surface.

9. An instrumental dial according to claim 7, wherein said grooves extend substantially concentrically to each other on said front surface.

10. An instrumental dial according to claim 7, wherein said grooves extend radially on said front surface.
